(19) United States
(12) Patent Application Publication
(10) Pub. No.: US 2005/0188820 A1
(43) Pub. Date: Sep. 1, 2005

(54) Apparatus and method for processing bell sound

(75) Inventors: Yong Chul Park, Seoul (KR); Jung Min Song, Seoul (KR); Jae Hyuck Lee, Seoul (KR); Jun Yup Lee, Yongin-si (KR)

Correspondence Address: JONATHAN Y. KANG, ESQ.;LEE, HONG, DEGERMAN, KANG & SCHMADEKA, 14th Floor, 801 S. Figueroa Street, Los Angeles, CA, 90017-5554, US

(73) Assignee: LG Electronics Inc.

(21) Appl. No.: 11/066,073

(22) Filed: Feb. 24, 2005

(30) Foreign Application Priority Data
Feb. 26, 2004 (KR) 13131/2004
Mar. 2, 2004 (KR) 13936/2004
Mar. 2, 2004 (KR) 13937/2004

(51) Int. Cl. G11C 5/00; G10H 7/00

(52) U.S. Cl. 84/603

(57) ABSTRACT

Provided are apparatus and method for processing bell sound in a wireless terminal, in which sound source samples for scales of bell sound contents are previously generated. In the apparatus, WAVE waveforms for all scales of the bell sound contents to be replayed are previously generated and stored, and music is outputted using the stored WAVE waveforms. Thus, the system load caused by real-time replay of the bell sound can be reduced remarkably.

### BACKGROUND OF THE INVENTION

1. Field of the Invention

The present invention relates to apparatus and method for processing bell sound in a wireless terminal, which are capable of reducing system resources and outputting high quality of sound.

2. Description of the Related Art

A wireless terminal is a device that can make a phone call or transmit and receive data. Such a wireless terminal includes a cellular phone, a Personal Digital Assistant (PDA), and the like.

A Musical Instrument Digital Interface (MIDI) is a standard protocol for data communication between electronic musical instruments. The MIDI is a standard specification for hardware and data structure that provide compatibility in the input/output between musical instruments or between musical instruments and computers through digital interface. Accordingly, the devices having the MIDI can share each other because compatible data are created therein.

The MIDI file includes actual musical score, sound intensity and tempo, instruction associated with musical characteristic, kinds of musical instruments, etc. However, unlike a wave file, the MIDI file does not store waveform information. Thus, a file size of the MIDI file is small and it is easy to add or delete musical instruments.

In the early stage, artificial sounds are created using a frequency modulation so as to make a sound of a musical instrument. That is, the sound of the musical instrument is created using the frequency modulation. At this point, a small capacity of memory is needed because additional sound sources are not used. However, this method has a disadvantage that cannot make a sound close to an original sound.

As the price of the memory is lower, sound sources are additionally produced according to the musical instruments and the respective scales thereof and are stored in the memory. Then, sounds are made by changing frequency and amplitude while maintaining inherent waveforms of the musical instruments. This is called a wave table technology. The wave table technology is widely used because it can generate natural sounds closest to original sounds.

FIG. 1 is a block diagram of an apparatus for replaying MIDI file according to the related art.

Referring to FIG. 1, the apparatus includes a MIDI parser 10 for extracting a plurality of scales and scale replay time, a MIDI sequencer 20 for sequentially outputting the extracted scale replay time, a wave table (not shown) for registering at least one sound source sample, and a frequency converter 30 for performing a frequency conversion into sound source samples corresponding to respective scales by using the at least one registered sound source sample every when the scale replay time is outputted.

Here, the MIDI file includes music information, including musical scores, such as note, scale, replay time, and timbre. The note is a notation representing the duration of the sound, and the replay time is the length of the sound. The scale is a pitch and seven sounds (e.g., do, re, mi, etc.) are used. The timbre represents a quality of sound and includes a unique property of the sound that can distinguish two sounds having the same pitch, intensity and length. For example, the timbre distinguishes a do-sound of a piano from a do-sound of a violin.

The wave table stores sound sources according to the musical instruments and the respective scales thereof. Generally, the scales ranges from step 1 to step 128. There is a limit in registering all sound sources of the scales in the wave table. Accordingly, sound source samples of several scales are only registered.

When a replay time of a specific scale is inputted, the frequency converter 30 checks whether sound sources of the respective scales exist in the wave table 130. Then, the frequency converter 30 performs a frequency conversion into sound sources assigned to the respective scales according to the checking result. Here, an oscillator can be used as the frequency converter 30.

If the sound sources of the respective scales do not exist in the wave table, a predetermined sound source sample is read from the wave table. Then, the frequency converter 30 performs a frequency conversion of the read sound source sample into a sound source sample corresponding to the respective scales. If a sound source of an arbitrary scale exists in the wave table, a corresponding sound source sample can be read from the wave table and then outputted, without any additional frequency conversion.

These processes are repeated every when the replay time of the scales is inputted, until the replay of the MIDI is finished.

However, if the frequency conversion is performed repeatedly every when the replay time of the scales is inputted, a lot of CPU resources are used. Also, the frequency conversion is performed on the scales together with the real-time replay, resulting in degradation of sound quality.

Since the related art apparatus uses a large amount of CPU resource, high quality of sound cannot be replayed without using higher CPU. Accordingly, there is a demand for a technology that can secure sound quality enough to listen to music sound by using a small amount of CPU resource.

Further, with the increase in the poly of the bell sound to be expressed, the system is overloaded much more when the bell sound is generated using only several sound source samples.

### SUMMARY OF THE INVENTION

Accordingly, the present invention is directed to an apparatus and method for processing bell sound that substantially obviates one or more problems due to limitations and disadvantages of the related art.

An object of the present invention is to provide an apparatus and method for processing bell sound, which can reduce system load in replaying the bell sound.

Another object of the present invention is to provide an apparatus and method for processing bell sound, which can previously generate sound samples corresponding to all sound replay information of the bell sound before replaying the bell sound.

A further another object of the present invention is to provide an apparatus and method for processing bell sound, in which sound sources are previously converted into sound source samples assigned to all scales and are stored, and the bell sound is replayed with the stored sound source samples.

A still further another object of the present invention is to provide an apparatus and method for processing bell sound, in which only a certain period of sound source corresponding to all scales of the bell sound is previously converted and stored, and the sound source is frequency-converted, and the stored sound source samples are repeatedly outputted one or more times.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, an apparatus for processing bell sound includes: a bell sound parser for parsing replay information from inputted bell sound contents; a sequencer for aligning the parsed replay information in order of time; a sound source storage unit where a plurality of first sound source samples are registered; a pre-processing unit for previously generating a plurality of second sound samples corresponding to the replay information by using the plurality of first sound source samples; and a music output unit for outputting the second sound source samples in time order of the replay information.

The pre-processing unit generates the second sound source samples by converting the first sound source samples into frequencies assigned to respective notes or scales.

In another aspect of the present invention, there is provided an apparatus for controlling bell sound, including: means for parsing replay information containing scales from inputted bell sound contents; means for aligning the parsed replay information in order of time; a sound source storage unit where a plurality of first sound source samples are previously registered, the first sound source samples including start data period and loop data period; a pre-processing unit for previously converting one period of the sound source samples into a plurality of second sound source samples having frequencies assigned to the scales; and a music output unit for repeatedly outputting at least one time in order of the replay information and time thereof without additional frequency conversion of the second sound source samples.

The second sound source samples are generated by frequency conversion of the start data period or loop data period of the first sound source samples.

According to a further another object of the present invention, there is provided a method for processing bell sound, including the steps of: parsing replay information from inputted bell sound contents; aligning the replay information in order of time; generating second sound source samples by converting the registered first sound source samples into frequencies corresponding to the replay information; and outputting the second sound source samples without additional frequency conversion in order of the replay information and time thereof.

According to the present invention, the system load due to the real-time replay can be reduced by previously generating and storing the sound source samples of the bell sound to be replayed.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a block diagram of an apparatus for replaying MIDI file according to the related art;

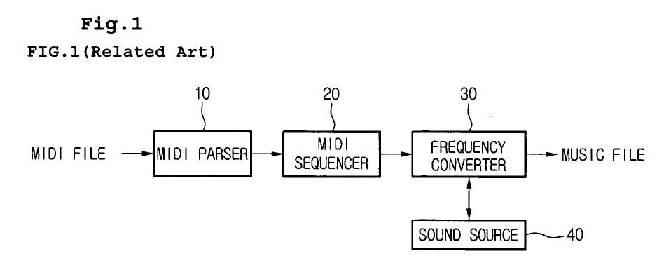

FIG. 2 is a block diagram of an apparatus for processing a bell sound according to a first embodiment of the present invention;

FIG. 3 is a block diagram of an apparatus for processing bell sound according to a second embodiment of the present invention;

FIG. 4 is a block diagram of an apparatus for processing bell sound according to a third embodiment of the present invention;

FIG. 5 is a block diagram of an apparatus for processing bell sound according to a fourth embodiment of the present invention;

FIG. 6 is a block diagram of an apparatus for processing bell sound according to a fifth embodiment of the present invention; and

FIG. 7 is a flowchart illustrating a method for processing bell sound according to a preferred embodiment of the present invention.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

### First Embodiment

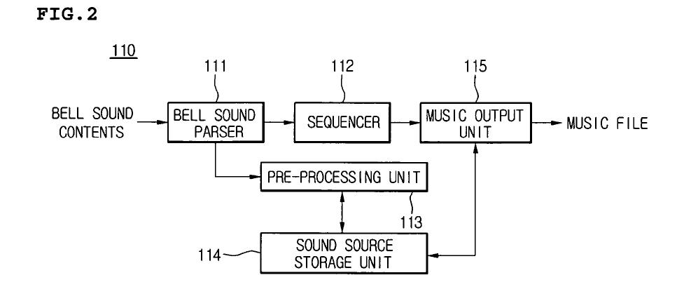

FIG. 2 is a block diagram of an apparatus for processing bell sound according to a first embodiment of the present invention.

Referring to FIG. 2, the apparatus 110 includes a bell sound parser 111 for parsing sound replay information from inputted bell sound contents, a sequencer 112 for aligning the sound replay information in order of time, a pre-processing unit 113 for generating in advance sound samples (hereinafter, referred to as second sound samples) corresponding to the sound replay information before replaying music sound, a sound source storage unit 114 where a plurality of sound source samples (hereinafter, referred to as first sound source samples) are registered and the second sound source samples are stored, and a music outputting unit 115 for reading the second sound source samples in order of the sound replay information and outputting it as music file.

Here, the bell sound can be comprised of MIDI file containing information for replaying the sound. The sound replay information is a musical score, including notes, scales, replay time, timbre, etc.

The note is a notation representing the duration of the sound, and the replay time is the length of the sound. The scale is a pitch and seven sounds (e.g., do, re, mi, etc.) are used. The timbre represents a quality of sound and includes a unique property of the sound that can distinguish two sounds having the same pitch, intensity and length. For example, the timbre distinguishes a do-sound of a piano from a do-sound of a violin.

In this embodiment, the bell sound contents may be one musical piece comprised of a start and an end of a song. Such a musical piece may be composed of a lot of scales and time durations thereof.

Also, the scale replay time means the replay time of the respective scales contained in the bell sound contents and is length information of the identical sound. For example, if a replay time of a re-sound is ⅛ second, it means that the re-sound is replayed for ⅛ second.

If the bell sound contents are inputted, the bell sound parser 111 parses the sound replay information from the bell sound contents and outputs the parsed sound replay information to the sequencer 112 and the pre-processing unit 113. At this time, information on the scale and the sound replay time is transferred to the sequencer 112, and all scales for replaying the sound are transmitted to the pre-processing unit 113.

The pre-processing unit 113 receives a plurality of scales and checks how many sound source samples (that is, the first sound source samples) representative of the musical instruments are stored in the sound source storage unit 114.

Here, after sampling actual sounds of various musical instruments, the first sound source samples corresponding to several representative scales are stored in the sound source storage unit 114. The first sound source samples include a Pulse Code Modulation (PCM) sound source, a MIDI sound source, and a wave table sound source. The wave table sound source stores the information of the musical instruments in a WAVE waveform. For example, the wave table sound source stores the sampled actual sounds of the various musical instruments.

Due to a problem of memory capacity in the terminal, the first sound source samples do not store all sounds with respect to all scales of the respective musical instruments (piano, guitar, etc.), but store several representative sounds. That is, in order for efficient utilization of the memory, one scale in each musical instrument does not have independent WAVE waveform, but several sounds are grouped and one representative WAVE waveform is used equally.

Generally, there is a limit in creating the first sound source samples into samples that can support all the scales according to 128 musical instruments and registering them. Therefore, only several representative sound source samples among the sound source samples are registered.

On the contrary, the scales parsed by the bell sound parser 111 may include scales corresponding to several tens to 128 musical instruments. Accordingly, the scales contained in the bell sound contents cannot be directly replayed using the first sound source samples that are previously registered in the sound source storage unit 114.

For this, the pre-processing unit 113 generates the second sound source samples by converting the first sound source samples corresponding to the scales to be replayed into the frequency previously assigned to all scales. That is, among the first sound source samples stored in the sound source storage unit 114, the scales to be relayed and a sampling rate may not be matched. For example, if a sampling rate of a piano sound source sample is 20 KHz, a sampling rate of a violin sound source sample may be 25 KHz, or a sampling rate of music to be relayed may be 30 KHz. Accordingly, prior to the replay, the first sound source samples can be previously frequency-converted into the second sound source samples.

The pre-processing unit 113 generates in advance the second sound source samples corresponding to the respective scales before replaying all scales, and the second sound source samples are stored in the sound source storage unit 114.

The music output unit 115 reads the sound source samples, which are stored in the sound source storage unit 114 according to the sound replay information aligned in order of time, from the sequencer 112, and then outputs them as the music file. That is, the music output unit 115 outputs the sound source samples corresponding to the respective scales without any additional frequency conversion for all scales.

The pre-processing unit 112 checks whether the second sound source samples corresponding to the scales inputted from the bell sound contents exist in the sound source storage unit 113. That is, the pre-processing unit 113 checks whether the sound source samples corresponding to one or more scales exist by comparing the scales transmitted from the bell sound parser 111 with the first sound source samples stored in the sound source storage unit 114.

At this point, if there exist the sound source samples that do not correspond to the scales among the first sound source samples, the sound source samples that do not correspond to the scales can be generated as the second sound source samples that correspond to the scales. If there exist the sound source samples that correspond to the scales among the first sound source samples, the sound source samples may remain in the first sound source sample region or may be constituted in the second sound source sample region.

In other words, the first sound source samples corresponding to the scales become the second sound source samples without any change. Also, if the second sound source samples corresponding to the scales do not exist in the first sound source samples, the second sound source samples corresponding to the scales are generated using the first sound source samples.

Here, the second sound source samples may use the sound source samples of the scales of the MIDI file and the sound source samples of the respective notes or the sound source samples of the respective timbres. Such second sound source samples are samples produced by the frequency conversion of the first sound source samples.

For example, in the case of 100 scale, if samples of the scale do not exist among the first sound source samples, sound source sample of 100 scale can be generated by the frequency conversion of one sound source sample (e.g., sound source sample of 70 scale) among the first sound source samples.

The second sound source samples can be stored in a separate region of the sound source storage unit 114. At this point, the second sound source samples stored in the sound source storage unit 114 are matched with all scales contained in the bell sound contents and the sound source samples corresponding to the scales. One musical piece can be entirely replayed by repeatedly replaying the second sound source samples one or more times.

Meanwhile, the sequencer 112 aligns the sound replay information from the bell sound parser 111 with reference to time. That is, the sound source information is aligned with reference to the time of the bell sound musical piece according to the musical instruments or tracks.

Based on the replay time of the respective scales outputted from the sequencer 112, the music output unit 115 sequentially reads the second sound source samples corresponding to the respective scales from the sound source storage unit 114 as much as the replay time of the respective scales. In this manner, the music file is replayed. Accordingly, it is unnecessary to simultaneously perform the frequency conversion while replaying the bell sound.

### Second Embodiment

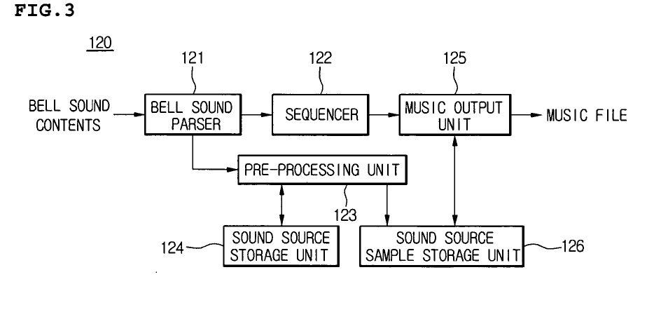

FIG. 3 is a block diagram of an apparatus for processing bell sound according to a second embodiment of the present invention. The apparatus 120 stores the sound source samples in independent storage units 124 and 126.

The sound source storage unit 124 stores several first sound source samples representative of the musical instruments, and the second sound source sample storage unit 126 stores the second sound source samples that are frequency-converted by a pre-processing unit 123.

Accordingly, a music output unit 125 can replay the music file by repeatedly requesting the second sound source samples stored in the sound source sample storage unit 126. Here, the music output unit 125 can selectively use the sound source storage unit 124 and the sound source sample storage unit 126 according to positions of the sound source samples having frequency of scale to be replayed.

### Third Embodiment

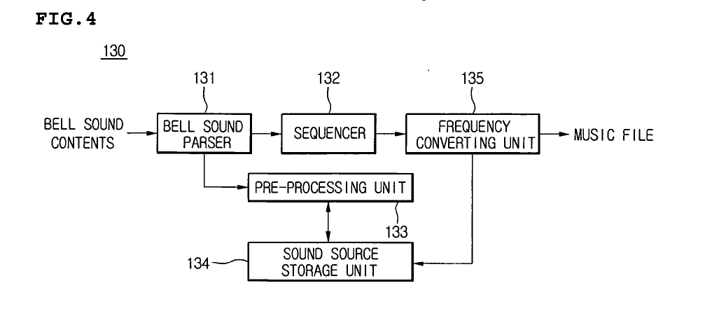

FIG. 4 is a block diagram of an apparatus for processing bell sound according to a third embodiment of the present invention. In FIG. 4, another embodiment of the pre-processing unit is illustrated.

Referring to FIG. 4, the apparatus 130 includes a bell sound parser 131, a sequencer 132, a sound source storage unit 134, a pre-processing unit 133, and a frequency converter 135.

The pre-processing unit 133 generates second sound source samples by a frequency conversion of first sound source samples stored in the sound source storage unit 134 corresponding to scales to be replayed.

At this point, the pre-processing unit 133 previously generates a plurality of second loop data by converting first loop data into frequencies assigned to the scales. Here, the first loop data are partial data of a plurality of first sound source samples. The second loop data are stored in the sound source storage unit 134.

The first sound source samples registered in the sound source storage unit 134 may be comprised of attack and decay data and loop data. Here, the attack and decay data represent a period where an initial sound is generated. The attack data is a data corresponding to a period where the initial sound increases to a maximum value, and the decay data is a data corresponding to a period where the initial data decreases from the maximum value to the loop data. Also, the loop data is a data corresponding to a period except the periods of the attack and decay data in the sound source sample. The sound is constantly maintained in the loop data. Such a loop data is a very short period data and can be repeatedly used several times according to the scale replay time.

For example, if the scale replay time is 3 seconds while the period of the loop data is 0.5 second, the loop data can be repeatedly used one time to five times for the scale replay time.

According to the related art, however, if the scale replay time is long, the loop data of the sound source samples are converted into the frequency of the corresponding scale every when they are repeated. Accordingly, when replaying MIDI file having many long scale replay time, the frequency converting unit continues to repeatedly replay the loop data, thus increasing an amount of operation process. Consequently, the CPU is much loaded, resulting in degradation of the system performance.

For this, the loop data of the sound source samples according to the respective scales are previously converted into the frequencies corresponding to the scales before replaying the bell sound contents. In replaying the bell sound, the loop data repeated one or more times in the respective scales are outputted without any additional frequency conversion, thus reducing the load of the CPU.

In more detail, the pre-processing unit 133 reads the first sound source samples corresponding to the scales from the sound source storage unit 134. At this point, a plurality of loop data (hereinafter, referred to as first loop data) are extracted from the first sound source samples. Then, the extracted first loop data are converted into the frequencies assigned to the respective scales to generate a plurality of second loop data. The second loop data are the second sound source data and are stored in a separate region of the sound source storage unit 134.

Here, the reason why only the first loop data among the sound source samples are frequency-converted is to avoid the process of performing the frequency conversion into the second loop data every when repeatedly replaying the first loop data later. Also, it is possible to reduce the overload of the CPU. Although the first sound source samples include the first attack and decay data except the first loop data, the first attack and decay data are replayed one time when replaying the respective scales. Thus, the overload of the CPU is solved, so that the additional frequency conversion is not needed in the pre-processing unit 133. Of course, if necessary, the first attack and decay data can also be previously frequency-converted.

The second loop data converted in the pre-processing unit 133 are stored in a separate region of the sound source storage unit 134. At this point, it is preferable that the second loop data are matched with the respective scales of the bell sound contents. Also, a plurality of second loop data can be provided to have starting points of different loop data corresponding to repetition replay time intervals.

For example, if sound source sample of 100 scale does not exist in the sound source storage unit 134, the loop data is extracted from one sound source sample (e.g., sound source sample of 70 scale) among the first sound source samples. Then, the extracted loop data can be converted into the frequency assigned to 100 scale. Accordingly, the frequency-converted loop data can be replayed as 100 scale according to the scale replay time of 100 scale. Of course, the attack and decay data must be replayed before replaying the loop data. This will be described later.

Meanwhile, the sequencer 132 temporally aligns the sound replay information, including the replay time of the scales from the bell sound parser 131. Here, after a predetermined time (that is, in a state that the loop data is frequency-converted and is registered), the scale replay time of the scales is sequentially outputted to the frequency converting unit 135.

The frequency converting unit 135 replays the second loop data registered in the sound source storage unit 134 according to the scale replay time of the scales, which is sequentially inputted from the sequencer 132.

That is, the frequency converting unit 135 reads the first attack and decay data registered in the sound source storage unit 134 according to the scale replay time of the scales and converts them into the frequencies assigned to the scales, and then generates the second attack and decay data. Thereafter, the frequency converting unit 135 reads the frequency-converted second loop data and repeatedly replays them according to the length of the scale replay time of the scales.

Here, if the length of the scale replay time is five times as long as the second loop data period, the corresponding second loop data can be repeatedly replayed five times. At this time, the second loop data are previously frequency-converted by the pre-processing unit 133 and are stored in the sound source storage unit 134. Any additional frequency conversion is not needed in the frequency converting unit 135. Accordingly, it is possible to solve the overload of the CPU, which is caused by the repeated frequency conversion in the frequency converting unit. Consequently, the performance or efficiency of the system can be improved.

It is possible to completely replay the music file according to the scale replay time of the scales outputted from the sequencer 132.

### Fourth Embodiment

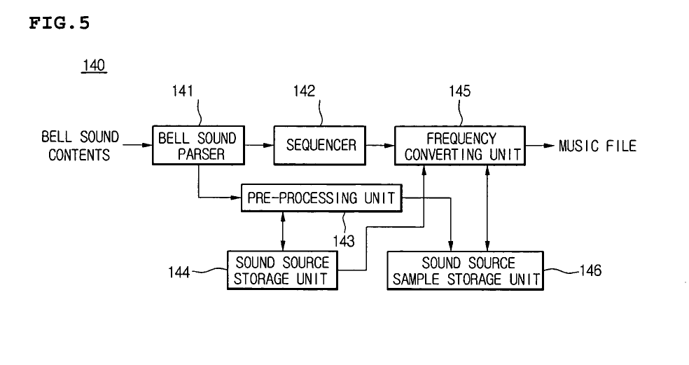

FIG. 5 is a block diagram of an apparatus for processing bell sound according to a fourth embodiment of the present invention. In this embodiment, the frequency conversion is previously performed on part of the sound source samples, that is, the loop data. Then, the loop data are stored in independent storage units 144 and 146.

The sound source storage unit 144 stores several first sound source samples representative of the musical instruments, and the second sound source sample storage unit 146 stores the second loop data, that is, the second sound source samples of all scales that are previously frequency-converted by a pre-processing unit 143.

Accordingly, the frequency converting unit 145 performs the frequency conversion of the first attach and decay data of the first sound source samples stored in the sound source storage unit 144. Also, the music file can be replayed by repeatedly requesting the second loop data stored in the sound source sample storage unit 146 one or more times according to the scale replay time.

### Fifth Embodiment

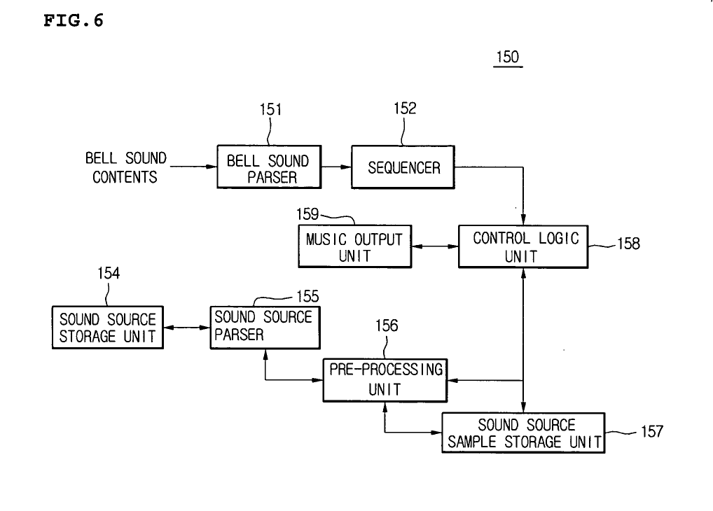

FIG. 6 is a block diagram of an apparatus for processing bell sound according to a fifth embodiment of the present invention.

Referring to FIG. 6, the apparatus 150 includes a bell sound parser 151 for parsing sound replay information from inputted bell sound contents, a sequencer 152 for aligning musical score information parsed by the bell sound parser 151 in order of time, a sound source storage unit 154, a sound source parser 155 for parsing first sound source samples corresponding to the sound replay information, a pre-processing unit 156 for generating second sound source samples of all scales to be replayed by a frequency modulation of the first sound source samples corresponding to the sound replay information, a sound source sample storage unit 157 for storing the second sound source samples, a control logic unit 158 for outputting the second sound source samples of the sound source sample storage unit 157 by using the sound replay information aligned in order of time by the sequencer 152, and a music output unit 159 for outputting the sound replay information and the second sound source samples as music file.

The apparatus 150 receives the first sound source samples corresponding to all scales of the bell sound contents and previously generates and stores WAVE waveform that are not contained in the sound source storage unit 154. In replaying the bell sound, the stored WAVE waveform is used.

The bell sound contents are contents having scale information. Except basic original sound, most of the bell sounds have MIDI-based music file format. The MIDI format includes a lot of pitches (musical score) and control signals according to tracks or musical instruments. The bell sound contents are transmitted to the wireless terminal in various manners. For example, the bell sound contents are downloaded through wireless/wired Internet or ARS service, or generated or stored in a wireless terminal.

In order to parse a specific bell sound format of the bell sound contents, the bell sound parser 151 parses note, scale, replay time, and timbre by analyzing a format of a bell sound to be currently replayed. That is, the bell sound parser 151 parses a lot of pitches and control signals according to tracks or musical instruments.

The sequencer 152 aligns the aligned musical score in order of a time and outputs it to the control logic unit 158.

Meanwhile, the first sound source samples are registered in the sound source storage unit 154. After sampling actual sounds of the various musical instruments, information on the musical instruments is stored in a WAVE waveform. The sound source storage unit 154 includes a Pulse Code Modulation (PCM) sound source, a MIDI sound source, a wave table sound source, etc. Among them, the wave table sound source stores the sampled actual sounds of the various musical instruments.

Due to a problem of memory capacity in the terminal, the first sound source samples do not store all sounds with respect to all scales of the respective musical instruments (piano, guitar, etc.), but store several representative sounds. That is, in order for efficient utilization of the memory, one scale in each musical instrument does not have independent WAVE waveform, but several sounds are grouped and one representative WAVE waveform is used equally.

If the information on the respective scales is transmitted to the pre-processing unit 156, the pre-processing unit 156 requests the first sound source samples 155 of the respective scales to the sound source parser 155. Here, in order to reduce the generation time of the second sound source samples, the scale information of the bell sound parser 151 can be directly transmitted to the pre-processing unit 156 or the sound source parser 155.

In order to replay the bell sound contents, the sound source parser 155 parses the sound source(s) corresponding to the scales of the bell sound contents from the sound source storage unit 154. At this point, the sound source parser 155 parses a plurality of first sound source samples corresponding to all scales.

The pre-processing unit 156 generates the second sound source samples corresponding to all scales by using the first sound source samples parsed by the sound source parser 155. That is, the pre-processing unit 156 receives several representative sound source samples and generates in advance the WAVE waveforms of all scales to be currently replayed.

The pre-processing unit 156 performs a frequency modulation of the first sound source samples so as to generate a scale to be currently replayed among the scales that are not registered in the sound source storage unit 154. For example, when the scale to be replayed is “sol-sol-la-la-sol-sol-mi” and only “do” sound is included in the first sound source samples, the pre-processing unit 156 generates in advance WAVE waveforms corresponding to “mi”, “sol” and “la” by using the do-sound.

The second sound source samples generated by the pre-processing unit 156 are stored in the sound source sample storage unit 157. For convenience of the access, the second sound source samples are matched with the respective scales. Also, the sound source sample storage unit 157 stores information about characteristic of the second sound source samples, for example, information about how the second sound source samples are repeatedly attached in the replay for 3 seconds, channel information (mono or stereo) and sampling rate.

Then, the control logic unit 158 accesses the second sound source samples according to the musical score aligned in order of time and outputs them to the music output unit 159.

The music output unit 159 does not analogizes all sounds of the scales to be currently replayed by using several representative sounds, but reads the second sound source samples stored in the sound source sample storage unit 157 and outputs them as music sound. That is, melody is generated using the stored WAVE waveform.

The bell sound synthesizing method includes FM synthesis and wave synthesis. The FM synthesis developed by YAMAHA Corp generates a sound by variously synthesizing sine waves as a basic waveform. Unlike the FM synthesis, the wave synthesis converts the sound itself into digital signal and stores the sound source. If necessary, the sound source is slightly changed.

The music output unit 159 reads the second sound source samples and replays them in real time. Even when the second sound source samples are replayed with a maximum ploy (e.g., 64 poly), the frequency conversion is not performed, resulting in reduction of the system load. That is, without the frequency conversion that generates all sounds by using several representative sound sources corresponding to all scales to be currently replayed, the sound is generated using the previously-created WAVE waveforms, resulting in reduction of the system load.

Also, the control logic unit 158 does not communicate with the sound source parser 155 but the pre-processing unit 156 and the sound source storage unit 157. Thus, it is unnecessary to perform the process of repeatedly requesting the parsing to the sound source parser 155 so as to read the sound information for the replay of the music. Consequently, the system load is greatly reduced. The control logic unit 158 can communicate with the pre-processing unit 156 and the sound source sample storage unit 157 through different interface or one interface.

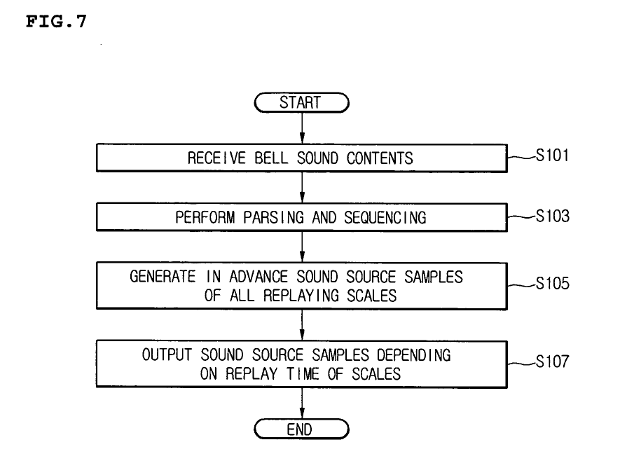

FIG. 7 is a flowchart illustrating a method for processing bell sound according to a preferred embodiment of the present invention.

Referring to FIG. 7, if the bell sound contents are inputted (S101), the bell sound contents are parsed and the parsed result is sequenced in order of time (S103).

At this point, the information parsed from the bell sound contents is the sound replay information and includes note, scale, replay time, and timbre. The parsed information is aligned in order of time according to tracks or musical instruments.

Then, the sound source samples of all scales corresponding to the parsed scales are previously generated by the frequency conversion (S105). That is, the sound source samples of all scales that do not exist in the sound source are previously generated by the frequency conversion and are stored in a buffer.

Here, the sound source samples that are frequency-converted in advance are sound source samples of all scales that do not exist in the sound source. Also, the sound source samples may be the loop data period or the attack and decay data period within the sound source samples of all scales that do not exist in the sound source.

Like this, using the sound source samples that are previously frequency-converted, the previously-created sound source samples are outputted according to the replay time of the sequenced scales (S107), thereby replaying the music file.

According to the present invention, when relaying the bell sound contents in the wireless terminal, the sound source samples of all scales of the bell sound contents to be replayed or the sound source samples of the scales generated one or more times are previously generated and stored. Thus, the bell sound can be replayed more conveniently and the system load can be reduced. Also, the bell sound can be smoothly replayed and thus a lot of chords can be expressed.

According to the present invention, the loop data of the sound source samples that can be repeatedly replayed are previously converted into the frequencies assigned to the corresponding note, and the loop data are outputted without any additional frequency conversion. Therefore, it is possible to prevent the overload of the CPU, which is caused by the real-time frequency conversion every when the loop data are repeated, thereby implementing the MIDI replay having higher reliability.

It will be apparent to those skilled in the art that various modifications and variations can be made in the present invention. Thus, it is intended that the present invention covers the modifications and variations of this invention provided they come within the scope of the appended claims and their equivalents.

1. An apparatus for processing bell sound, comprising:
a bell sound parser for parsing replay information from inputted bell sound contents;
a sequencer for aligning the parsed replay information in order of time;
a sound source storage unit where a plurality of first sound source samples are registered;
a pre-processing unit for previously generating a plurality of second sound samples corresponding to the replay information by using the plurality of first sound source samples; and
a music output unit for outputting the second sound source samples in time order of the replay information.

2. The apparatus according to claim 1, further comprising a sound source sample storage unit for storing the second sound source samples.

3. The apparatus according to claim 1, wherein the first sound source samples and the second sound source samples are stored in independent regions of the sound source storage unit.

4. The apparatus according to claim 1, wherein the replay information includes a plurality of notes and scales, replay time, and timbre, which are contained in the bell sound contents.

5. The apparatus according to claim 1, wherein the pre-processing unit generates the second sound source samples by converting the first sound source samples into frequencies assigned to respective notes.

6. The apparatus according to claim 1, wherein the pre-processing unit generates the second sound source samples by converting the first sound source samples into frequencies assigned to respective scales.

7. The apparatus according to claim 1, wherein the pre-processing unit generates the second sound source samples by converting the first sound source samples into frequencies assigned to respective timbres.

8. The apparatus according to claim 1, wherein the pre-processing unit frequency-converts the first sound source samples of sound source corresponding to at least one of respective notes, scales and sound quality into the second sound source samples according to the notes, the scales or the sound quality.

9. The apparatus according to claim 1, wherein the pre-processing unit generates the second sound source samples by converting the first sound source samples into sampling rates to be replayed.

10. The apparatus according to claim 1, wherein the second sound source samples are note-based samples that are repeated one or more times.

11. The apparatus according to claim 1, further comprising a sound source parser disposed between the sound source and the pre-processing unit to parse sound source samples corresponding to respective scales.

12. An apparatus for controlling bell sound, comprising:
means for parsing replay information containing scales from inputted bell sound contents;
means for aligning the parsed replay information in order of time;
a sound source storage unit where a plurality of first sound source samples are previously registered, the first sound source samples including start data period and loop data period;
a pre-processing unit for previously converting one period of the sound source samples into a plurality of second sound source samples having frequencies assigned to the scales; and
a music output unit for repeatedly outputting at least one time in order of the replay information and time thereof without additional frequency conversion of the second sound source samples.

13. The apparatus according to claim 12, wherein the second sound source samples are generated by frequency conversion of the loop data period of the first sound source samples.

14. The apparatus according to claim 12, wherein the second sound source samples are generated by frequency conversion of the start data period of the first sound source samples.

15. The apparatus according to claim 12, wherein the second sound source samples are generated by frequency conversion of the loop data and the start data period of the first sound source samples.

16. The apparatus according to claim 13, wherein the second sound source samples are period samples based on respective scales.

17. The apparatus according to claim 14, wherein the start data period includes attack and decay data periods of the sound source samples.

18. The apparatus according to claim 12, wherein the music output unit converts specific period data of the first sound source samples corresponding to respective scales into frequencies identical to the second sound source samples so as to output music with frequencies assigned to the respective scales.

19. The apparatus according to claim 12, wherein the music output unit performs a real-time frequency conversion of the start data period corresponding to respective scales in time order of the replay information, and outputs the loop data periods of respective scales at least one time without frequency conversion according to the scale replay time.

20. An apparatus for processing bell sound, comprising:
a bell sound parser for parsing replay information containing a plurality of scales from inputted bell sound contents;
a sequencer for aligning the parsed replay information in order of time;
a sound source where a plurality of first sound source samples are registered;
a sound source parser for parsing an arbitrary first sound source sample registered in the sound source;
a pre-processing unit for generating second sound source samples based on scales by frequency conversion of the first sound source samples corresponding to the scales;
a sound source sample storage unit for storing the second sound source samples based on the scales, which are generated by the pre-processing unit;
a control logic unit for requesting the stored second sound source samples based on the scales in time order of the replay information; and
a music output unit for outputting the second sound source samples as music.

21. A method for processing bell sound, comprising the steps of:
parsing replay information from inputted bell sound contents;
aligning the replay information in order of time;
generating second sound source samples by converting the registered first sound source samples into frequencies corresponding to the replay information; and
outputting the second sound source samples without additional frequency conversion in order of the replay information and time thereof.

22. The method according to claim 21, wherein the second sound source samples are WAVE waveform for all notes and/or scales of a replaying music.

23. The method according to claim 21, wherein the second sound source samples are samples corresponding to notes and/or scales that are repeated one or more times in a replaying music.

24. The method according to claim 21, wherein the stored second sound source samples are matched with notes and/or scales to be replayed.

25. The method according to claim 21, wherein the second sound source samples include one or more of information on repeated replay, mono or stereo channel information, and sampling rate.

26. The method according to claim 21, wherein the second sound source samples are different from frequencies of the first sound source samples.
